(19) United States
(12) Patent Application Publication
(10) Pub. No.: US 2026/0068090 A1
(43) Pub. Date: Mar. 5, 2026

(54) COLD PLATE

(71) Applicant: NIDEC CORPORATION, Kyoto (JP)

(72) Inventors: Takaya OKUNO, Kyoto (JP); Kosei OZAKI, Kyoto (JP); Shogo TORIUMI, Kyoto (JP)

(21) Appl. No.: 19/308,500

(22) Filed: Aug. 25, 2025

(30) Foreign Application Priority Data
Aug. 30, 2024 (JP) 2024-148631

(51) Int. Cl. H05K 7/20

(52) U.S. Cl. CPC H05K 7/20272; H05K 7/20254

(57) ABSTRACT

A cold plate includes a bottom wall, a top wall, a side wall, an inlet, an outlet, and a blade group. The bottom wall includes a lower surface. The top wall covers an upper surface of the bottom wall. The side wall connects the bottom wall and the top wall, and defines a refrigerant flow path through which a refrigerant is capable of flowing into the refrigerant flow path through the inlet and out of the refrigerant flow path through the outlet. The blade group is in the refrigerant flow path, and includes linearly extending blades arranged in a direction intersecting an extending direction of the blades. A plurality of blade groups are arranged side by side with a gap in the extending direction of the blades, and a plurality of the inlets are correspondingly positioned with respect to the plurality of blade groups.

### CROSS-REFERENCE TO RELATED APPLICATIONS

The present invention claims priority under 35 U.S.C. § 119 to Japanese Patent Application No. 2024-148631, filed on Aug. 30, 2024, the entire contents of which are hereby incorporated herein by reference.

### 1. FIELD OF THE INVENTION

The present invention relates to cold plates.

### 2. BACKGROUND

A conventional cold plate includes a bottom wall, a top wall, a side wall, an inlet, an outlet, and a blade group. The bottom wall includes a lower surface to be in thermal contact with a heat generating component. The top wall covers an upper surface of the bottom wall. The side wall connects the bottom wall and the top wall, and forms a refrigerant flow path through which a refrigerant flows. The refrigerant flows into the refrigerant flow path through the inlet. The refrigerant flows out of the refrigerant flow path through the outlet. The blade group is disposed in the refrigerant flow path, and is configured by arranging a plurality of linearly extending blades in a direction intersecting the extending direction. The inlet and the outlet are disposed to face each other with the blade group interposed therebetween.

However, in the conventional cold plate, when the blade group is elongated in the extending direction of the blades, there is a possibility that the pressure loss when the refrigerant flows through the blade group increases.

### SUMMARY

According to an example embodiment of the present invention, a cold plate includes a bottom wall, a top wall, a side wall, an inlet, an outlet, and a blade group. The bottom wall includes a lower surface to be in thermal contact with a heat generating component. The top wall covers an upper surface of the bottom wall. The side wall connects the bottom wall and the top wall, and defines a refrigerant flow path through which a refrigerant is capable of flowing. The refrigerant is capable of flowing into the refrigerant flow path through the inlet and out of the refrigerant flow path through the outlet. The blade group is in the refrigerant flow path, and includes linearly extending blades arranged in a direction intersecting an extending direction of the blades. A plurality of the blade groups are arranged side by side with a gap in the extending direction of the blades, and a plurality of inlets are correspondingly positioned with respect to the plurality of blade groups.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a perspective view of a cold plate according to an example embodiment of the present invention.

FIG. 2 is an exploded perspective view of a cold plate according to an example embodiment of the present invention.

FIG. 3 is a longitudinal sectional perspective view of a cold plate according to an example embodiment of the present invention.

FIG. 4 is a perspective view of a top wall of a cold plate according to an example embodiment of the present invention.

FIG. 5 is a horizontal sectional perspective view of a top wall of a cold plate according to an example embodiment of the present invention.

FIG. 6 is a top view of a bottom wall of a cold plate according to an example embodiment of the present invention.

### DETAILED DESCRIPTION

Example embodiments of the present invention will be described below with reference to the drawings. In the present application, the facing direction of a bottom wall 12 and a top wall 13 is referred to as a “vertical direction”. In addition, a direction in which the top wall 13 is disposed with respect to the bottom wall 12 is referred to as “upward”, and a direction opposite to the direction in which the top wall 13 is disposed is referred to as “downward”. Moreover, in the present application, the shape and positional relationships of the respective parts will be described under the assumption that a direction orthogonal to the “vertical direction” is referred to as a “horizontal direction”.

A direction in which a blade 151 of a cold plate 10 extends is defined as an extending direction (X1-X2), and a direction in which the blades 151 are arranged is defined as an arrangement direction (Y1-Y2). In the present example embodiment, the vertical direction (Z1-Z2) is orthogonal to the extending direction (X1-X2) and the arrangement direction (Y1-Y2). However, the vertical direction and the horizontal direction are defined merely for convenience of description, and the orientations of the cold plate 10 according to the present invention at the time of manufacture and at the time of use are not limited.

In addition, a “parallel direction” in the present application includes a substantially parallel direction. Moreover, an “orthogonal direction” in the present application includes a substantially orthogonal direction.

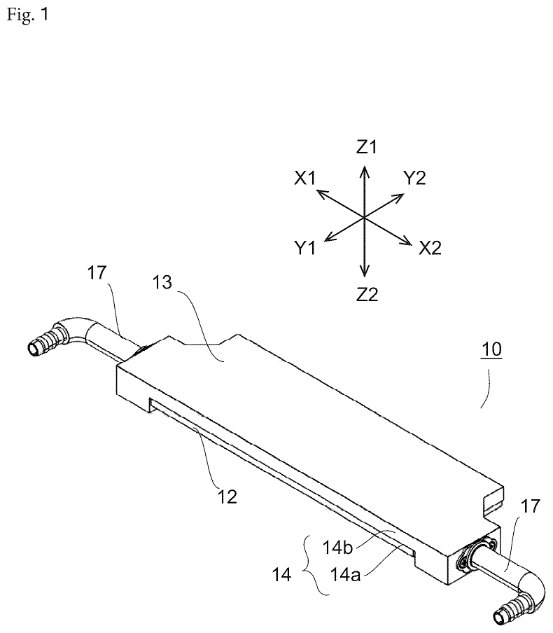

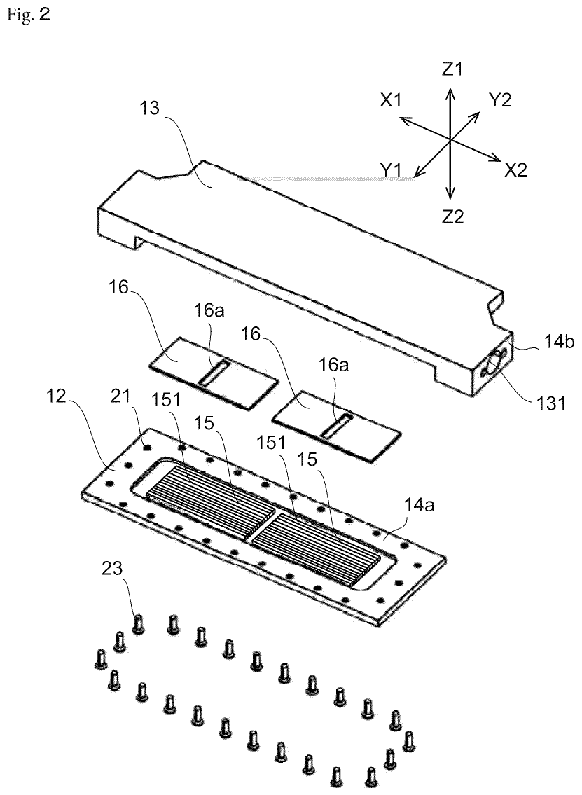

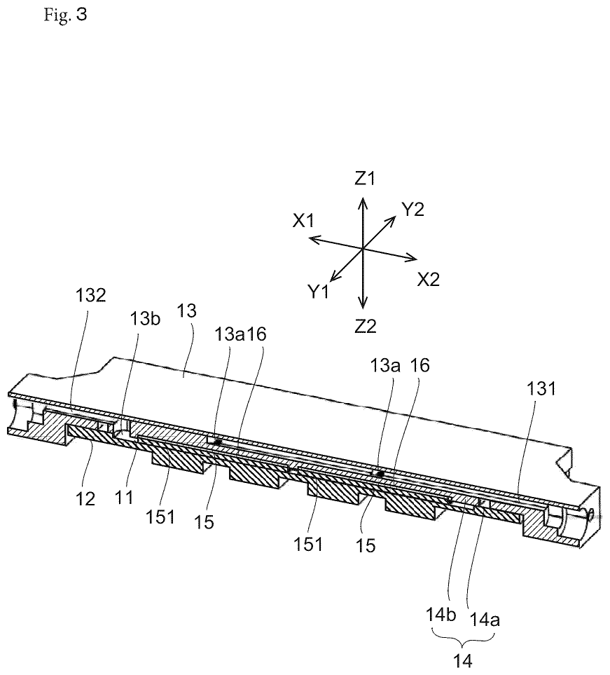

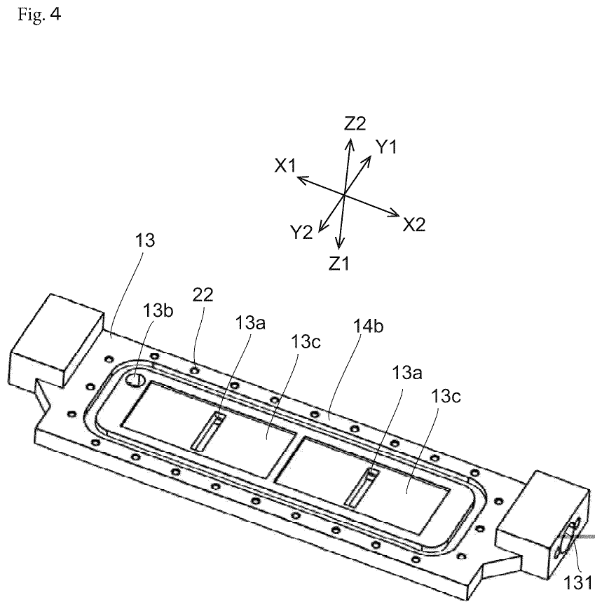

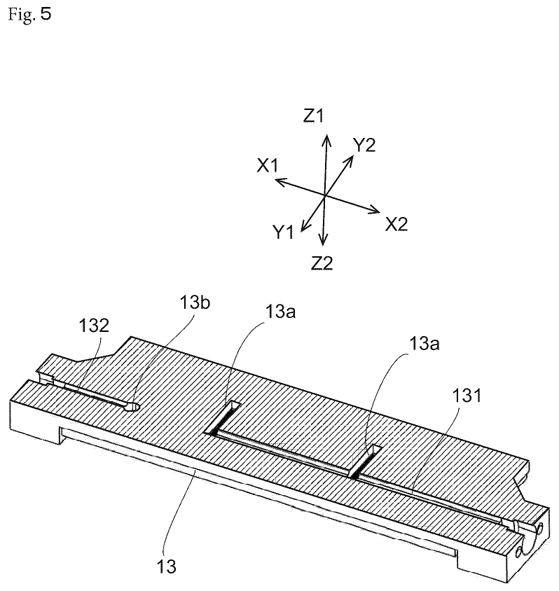

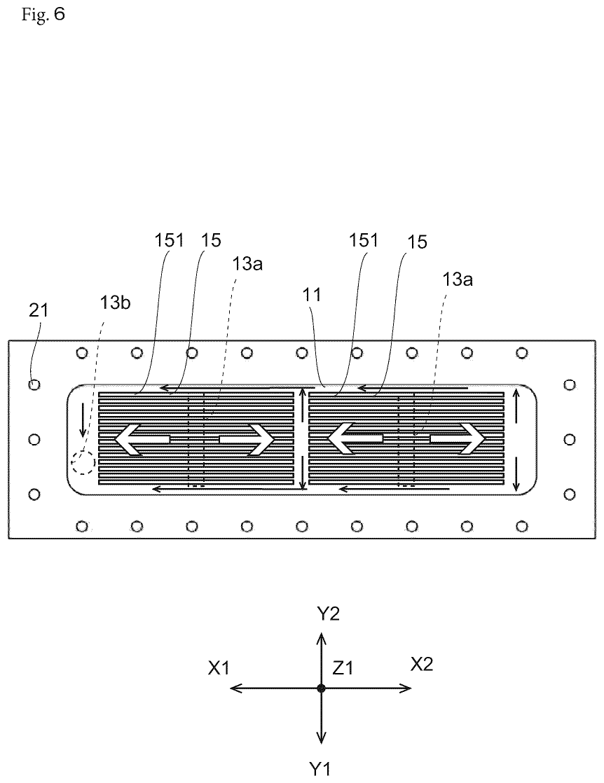

A cold plate according to an example embodiment of the present invention will be described. FIG. 1 is a perspective view of a cold plate 10 according to a first example embodiment of the present invention, and FIG. 2 is an exploded perspective view of the cold plate 10. FIG. 3 is a longitudinal sectional perspective view of the cold plate 10. FIG. 4 is a perspective view of the top wall 13 as viewed from downward Z2. FIG. 5 is a horizontal sectional perspective view of the top wall 13. FIG. 6 is a top view of the bottom wall 12. In FIG. 6, the flowing direction of the refrigerant is indicated by an arrow, and an inlet 13a and an outlet 13b are indicated by broken lines.

The cold plate 10 is made of metal having high thermal conductivity such as copper or aluminum, and includes the bottom wall 12, the top wall 13, a side wall 14, a blade group 15, and an intermediate member 16. In the present example embodiment, the cold plate 10 has a rectangular shape in the top view. More specifically, the bottom wall 12 and the top wall 13 have a rectangular plate shape extending horizontally in the top view, and the top wall 13 has two corner portions cut away. Note that the bottom wall 12 and the top wall 13 of the present example embodiment each have a quadrangular shape in the top view, but are not limited thereto, and may have, for example, a polygonal shape having a plurality of corners in the top view or a circular shape.

The bottom wall 12 has a lower surface to be in thermal contact with a heat generating component (not illustrated) to be cooled such as a CPU. The top wall 13 covers the upper surface of the bottom wall 12. The lower surface of the top wall 13 has a recess 13c recessed upward Z1 (see FIG. 4). The intermediate member 16 is disposed inside the recess 13c. This facilitates positioning of the intermediate member 16.

The side wall 14 connects the bottom wall 12 and the top wall 13, and forms a refrigerant flow path 11 through which a refrigerant flows. The refrigerant flow path 11 is formed in an internal space surrounded by the bottom wall 12, the top wall 13, and the side wall 14. The refrigerant is liquid, and for example, an antifreeze such as an ethylene glycol aqueous solution or a propylene glycol aqueous solution, pure water, or the like is used.

In the present example embodiment, the side wall 14 includes a first side wall portion 14a protruding upward Z1 from the upper surface of the bottom wall 12 and a second side wall portion 14b protruding downward Z2 from the lower surface of the top wall 13. The upper surface of the first side wall portion 14a and the lower surface of the second side wall portion 14b are joined. In the present example embodiment, the side wall 14 is configured of the first side wall portion 14a and the second side wall portion 14b, but may be configured of only one of them. That is, the upper surface of the first side wall portion 14a may be joined to the lower surface of the top wall 13 without the second side wall portion 14b, or the lower surface of the second side wall portion 14b may be joined to the upper surface of the bottom wall 12 without the first side wall portion 14a.

In the present example embodiment, the first side wall portion 14a is disposed on the peripheral edge of the bottom wall 12, but may be disposed on the inner side (the side approaching the blade group 15) of the peripheral edge of the bottom wall 12. In the present example embodiment, the second side wall portion 14b is disposed on the peripheral edge of the top wall 13, but may be disposed on the inner side (the side approaching the blade group 15) of the peripheral edge of the top wall 13.

The first side wall portion 14a has a first screw hole 21 penetrating in the vertical direction (Z1-Z2), and the second side wall portion 14b has a second screw hole 22 formed to be recessed upward Z1 (see FIG. 4). A plurality of the first screw holes 21 and a plurality of the second screw holes 22 are disposed to surround the refrigerant flow path 11. Further, the bottom wall 12 and the top wall 13 are fixed by aligning the first screw hole 21 and the second screw hole 22 and screwing them with a screw 23.

The blade group 15 is disposed in the refrigerant flow path 11, and is configured by arranging a plurality of linearly extending blades 151 in a direction (Y1-Y2) intersecting the extending direction (X1-X2). A plurality of the blade groups 15 are arranged side by side with a gap in the extending direction (X1-X2) of the blades 151. In the present example embodiment, two blade groups 15 are arranged side by side, but three or more blade groups may be arranged side by side with a gap therebetween in the extending direction (X1-X2) of the blades 151.

The plurality of blades 151 are arranged side by side on the upper surface of the bottom wall 12, and in the present example embodiment, the blades 151 are the same member as the bottom wall 12. The blades 151 are formed by, for example, cutting the upper surface of the bottom wall 12. As a result, thermal conductivity from the bottom wall 12 to the refrigerant flowing through the refrigerant flow path 11 via the blades 151 is improved. The blade 151 may be formed of a member different from the bottom wall 12. For example, the blade 151 may be formed in a plate-shaped base member, and the bottom wall 12 and the base member may be welded.

The intermediate member 16 is disposed between the top wall 13 and each blade group 15. The intermediate member 16 is made of, for example, sheet-shaped rubber. The intermediate member 16 has a flow hole 16a penetrating in the vertical direction (Z1-Z2). In the present example embodiment, the flow hole 16a extends in the arrangement direction (Y1-Y2). The flow hole 16a faces the inlet 13a, to be described below, in the vertical direction (Z1-Z2). The width of the flow hole 16a in the arrangement direction (Y1-Y2) is the same as the width of the inlet 13a in the arrangement direction (Y1-Y2), and the width of the blade group 15 in the arrangement direction (Y1-Y2) is larger than the width of the inlet 13a in the arrangement direction (Y1-Y2). As a result, the refrigerant smoothly flows into each blade group 15 through the inlet 13a and the flow hole 16a.

The upper surface of the intermediate member 16 is in contact with the top wall 13, and the lower surface of the intermediate member 16 is in contact with each blade group 15. Since the intermediate member 16 is disposed, the gap between the top wall 13 and the blades 151 in the vertical direction (Z1-Z2) is closed. Thus, in each blade group 15, the refrigerant flowing between the adjacent blades 151 can be prevented from flowing into the gap in the vertical direction (Z1-Z2) between the top wall 13 and the blades 151. Accordingly, thermal conductivity from the bottom wall 12 to the refrigerant flowing through the refrigerant flow path 11 via the blades 151 is further improved. As the intermediate member 16, a resin sheet may be used instead of rubber.

When the pump is driven, the refrigerant circulates through the refrigerant flow path 11. The heat of the heat generating component (not illustrated) is transmitted to the bottom wall 12 of the cold plate 10. The heat transmitted to the bottom wall 12 is transmitted to the refrigerant flowing through the refrigerant flow path 11. The refrigerant radiates heat via a radiator (not illustrated). As described above, the heat generating component can be cooled.

The cold plate 10 further includes the inlet 13a through which the refrigerant flows into the refrigerant flow path 11, the outlet 13b through which the refrigerant flows out of the refrigerant flow path 11, a refrigerant supply path 131, and a refrigerant discharge path 132 (see FIG. 3).

In the present example embodiment, the inlet 13a, the outlet 13b, the refrigerant supply path 131, and the refrigerant discharge path 132 are formed in the top wall 13. The refrigerant discharge path 132 extends linearly on an extension line of the linearly extending refrigerant supply path 131. The inlet 13a and the outlet 13b are open to the lower surface of the top wall 13, and a plurality of the inlets 13a are arranged corresponding to the respective blade groups 15.

The refrigerant flowing into the refrigerant flow path 11 from the respective inlets 13a flows through the respective blade groups 15 to flow toward the outlet 13b. In the present example embodiment, the gap in the extending direction (X1-X2) between the adjacent blade groups 15 and the gap in the arrangement direction (Y1-Y2) between the blade group 15 and the side wall 14 are larger than the gap in the arrangement direction (Y1-Y2) between the adjacent blades 151 (see FIG. 6). The gap in the extending direction (X1-X2) between the adjacent blade groups 15 is larger than the width of the inlet 13a in the extending direction (X1-X2).

Therefore, the flow path resistance between the blades 151 adjacent in the arrangement direction (Y1-Y2) is higher than the flow path resistance outside each blade group 15. As a result, the refrigerant that has passed through each blade group 15 from each inlet 13a flows through the gap between the adjacent blade groups 15 and flows outside the blade group 15 having a low flow path resistance toward the outlet 13b. The refrigerant flows through the gap between the adjacent blade groups 15.

Thus, since the plurality of blade groups 15 are arranged in the extending direction (X1-X2) and the plurality of inlets 13a corresponding to the respective blade groups 15 are provided, the flowing distance of the refrigerant flowing through the blade group 15 can be shortened as compared with the case where one long blade group 15 is disposed in the extending direction (X1-X2) and one corresponding inlet 13a is provided. Therefore, the pressure loss of the refrigerant can be reduced in the entire refrigerant flow path 11. Therefore, the power consumption of the pump that circulates the refrigerant in the refrigerant flow path 11 can be reduced.

The heat of the heat generating component is transmitted to the lower surface of the bottom wall 12, and is transmitted to the refrigerant flowing through the refrigerant flow path 11 via each blade group 15. At this time, the refrigerant having the same temperature is supplied to each blade group 15 from each inlet 13a. Therefore, the cooling effect in each blade group 15 can be made uniform.

The inlet 13a is disposed to face a central portion in the extending direction (X1-X2) of the blade 151 in the vertical direction (Z1-Z2) (see FIG. 6). The refrigerant having flown into the refrigerant flow path 11 from the inlet 13a branches off to flow on both sides in the extending direction (X1-X2) of the blade 151 (see FIG. 6). At this time, in each blade group 15, the distance by which the refrigerant flowing to one side X1 in the extending direction passes through the blades 151 is the same as the distance by which the refrigerant flowing to the other side X2 in the extending direction passes through the blades 151.

As a result, the flow path resistance of the refrigerant flowing to one side X1 in the extending direction and the flow path resistance of the refrigerant flowing to the other side X2 in the extending direction become the same. Therefore, the amounts of the refrigerant branched and flowing on both sides in the extending direction (X1-X2) become equal. As a result, the cooling effect in the extending direction (X1-X2) in each blade group 15 can be made uniform.

Further, for example, when the inlet 13a is arranged to face the end on the other side X2 of the blade 151 in the downward direction (Z1-Z2), the refrigerant flows from the end on the other side X2 of the blade 151 to the end on the one side X1. At this time, the flow distance of the refrigerant flowing through the blade group 15 increases, and the temperature difference increases between the upstream side and the downstream side in the refrigerant flowing direction. Therefore, by arranging the inlet 13a so as to face the central portion in the extending direction (X1-X2) of the blade 151 in the vertical direction (Z1-Z2), the cooling effect in the extending direction (X1-X2) in each blade group 15 can be made more uniform.

The inlet 13a extends in the arrangement direction (Y1-Y2) of the blades 151 (See FIGS. 5 and 6). The inlet 13a is connected to the refrigerant supply path 131 at an end on one side Y1 in the arrangement direction of the blades 151. The refrigerant flows between the blades 151 arranged in the arrangement direction (Y1-Y2) while flowing from the end of the one side Y1 in the arrangement direction of the inlet 13a to the other side Y2 in the arrangement direction. As a result, the refrigerant supply path 131 and the inlet 13a can be formed in a simple shape and disposed compactly inside the top wall 13 as compared with the case where the refrigerant is branched from the inlet 13a to both sides in the arrangement direction (Y1-Y2), and the cold plate 10 can be downsized.

The outlet 13b is disposed at one location at an end of refrigerant flow path 11 in the extending direction (X1-X2) of blade 151. The outlet 13b is connected to the refrigerant discharge path 132. Since the outlet 13b is arranged at an end of the refrigerant flow path 11 in the extending direction (X1-X2) of the blade 151, it is possible to reduce collision of the refrigerant passing through the blade group 15 toward the outlet 13b around the outlet 13b. As a result, the pressure loss of the refrigerant can be further reduced in the entire refrigerant flow path 11. Moreover, since the outlet 13b is provided at one location, it is possible to simplify the refrigerant pipe connected to the outlet 13b to further downsize the entire cold plate 10 and further reduce the manufacturing cost of the cold plate 10.

The refrigerant supply path 131 supplies the refrigerant to the refrigerant flow path 11 via the inlet 13a. The refrigerant discharge path 132 is connected to the outlet 13b and discharges the refrigerant from the refrigerant flow path 11. In the present example embodiment, the refrigerant supply path 131 and the refrigerant discharge path 132 are formed by cutting the inside of the top wall 13 into a columnar shape and are formed integrally with the top wall 13. An end of the refrigerant supply path 131 on an upstream side in the refrigerant flowing direction is open to the side wall 14. An end of the refrigerant discharge path 132 on a downstream side in the refrigerant flowing direction is open to the side wall 14. In the present example embodiment, the ends of the refrigerant supply path 131 and the refrigerant discharge path 132 are open to the second side wall portion 14b.

Since the refrigerant supply path 131 and the refrigerant discharge path 132 are formed integrally with the top wall 13, the manufacturing cost of the cold plate 10 can be reduced. Since the refrigerant supply path 131 and the refrigerant discharge path 132 are disposed inside the top wall 13, the upper surface of the top wall 13 can be flattened to downsize the cold plate 10 in the vertical direction (Z1-Z2). Accordingly, the cold plate 10 can be easily attached to the actual machine including the heat generating component.

The refrigerant supply path 131 and the refrigerant discharge path 132 have ends on the upstream side in the refrigerant flowing direction that are open to the side wall 14, and are connected to a pump (not illustrated) via a refrigerant pipe (not illustrated) connected to an elbow 17 (see FIG. 1). Accordingly, the cold plate 10 can be further downsized in the vertical direction (Z1-Z2).

The refrigerant supply path 131 extends in a direction away from the outlet 13b along the extending direction (X1-X2) of the blade. As a result, the refrigerant flowing from the refrigerant supply path 131 into the refrigerant flow path 11 smoothly flows toward the outlet 13b through each blade group 15. Therefore, the pressure loss of the refrigerant can be further reduced in the entire refrigerant flow path 11.

The refrigerant discharge path 132 extends in a direction away from the inlet 13a along the extending direction (X1-X2) of the blade. As a result, the refrigerant flowing along the extending direction (X1-X2) of the blade is smoothly discharged to the refrigerant discharge path 132 via the outlet 13b. Therefore, the pressure loss of the refrigerant can be further reduced in the entire refrigerant flow path 11.

The refrigerant supply path 131 branches inside the top wall 13 and is connected to each inlet 13a. By supplying the refrigerant in a branched manner to each inlet 13a from the refrigerant supply path 131, it is possible to suppress variations in the temperature of the refrigerant flowing into each inlet 13a. As a result, the cooling effect in each blade group 15 can be made more uniform. Moreover, by branching the refrigerant supply path 131 inside the top wall 13, it is possible to simplify a member such as a refrigerant pipe connected to the cold plate 10 to further downsize the entire cold plate 10 and further reduce the manufacturing cost of the cold plate 10.

Although the refrigerant supply path 131 and the refrigerant discharge path 132 are formed integrally with the top wall 13 in the present example embodiment, they may be formed separately from the top wall 13. For example, the inlet 13a and the outlet 13b penetrating the top wall 13 in the vertical direction (Z1-Z2) may be formed, and the inlet 13a and the outlet 13b may be connected to a refrigerant pipe (not illustrated) via an elbow. At this time, the refrigerant pipe is disposed on the upper surface of the top wall 13, and the refrigerant supply path 131 and the refrigerant discharge path 132 are formed inside the refrigerant pipe. The refrigerant pipe may be incorporated in the top wall 13 to form the refrigerant supply path 131 and the refrigerant discharge path 132.

The above example embodiments are merely examples of the present invention. The configuration of the example embodiments may be appropriately changed without departing from the technical ideas of example embodiments of the present invention. In addition, the example embodiments may be implemented in combination within a feasible range. For example, in the present example embodiment, the inlet 13a is connected to the refrigerant supply path 131 at the end on the one side Y1 in the arrangement direction of the blades 151, but may be connected to the refrigerant supply path 131 at the central portion in the arrangement direction (Y1-Y2) of the blades 151.

As described above, a cold plate (10) according to an example embodiment of the present disclosure includes a bottom wall (12) that includes a lower surface to be in thermal contact with a heat generating component, a top wall (13) that covers an upper surface of the bottom wall, a side wall (14) that connects the bottom wall and the top wall and defines a refrigerant flow path (11) through which a refrigerant is capable of flowing, an inlet (13a) through which the refrigerant is capable of flowing into the refrigerant flow path, an outlet (13b) through which the refrigerant is capable of flowing out of the refrigerant flow path, and a blade group (15) that is in the refrigerant flow path and includes a plurality of blades (151) extending linearly and arranged in a direction intersecting an extending direction (X1-X2), in which a plurality of the blade groups are arranged side by side in the extending direction (X1-X2) of the blades, and a plurality of the inlets are correspondingly positioned with respect to the plurality of blade groups (first configuration).

In the first configuration, the cold plate may be configured such that the outlet is at one location at an end of the refrigerant flow path in the extending direction (X1-X2) of the blade (second configuration).

In the first or second configuration, the cold plate may be configured to further include a refrigerant supply path (131) that supplies the refrigerant to the refrigerant flow path, and may be configured such that the refrigerant supply path is branched and connected to each of the inlets (third configuration).

In any one of the first to third configurations, the cold plate may be configured such that the refrigerant supply path is integral with the top wall, and an end of the refrigerant supply path on an upstream side in a flowing direction of the refrigerant is opened to the side wall (fourth configuration).

In any one of the first to fourth configurations, the cold plate may be configured such that the refrigerant supply path extends in a direction away from the outlet along the extending direction of the blade (fifth configuration).

In any one of the first to fifth configurations, the cold plate may be configured such that the inlet extends in the arrangement direction (Y1-Y2) of the blades, and is connected to the refrigerant supply path at one end in the arrangement direction of the blades (sixth configuration).

In any one of the first to sixth configurations, the cold plate may be configured to further include a refrigerant discharge path (132) to discharge the refrigerant from the refrigerant flow path, and may be configured such that the refrigerant discharge path is connected to the outlet and extends in a direction away from the inlet along the extending direction of the blade (seventh configuration).

In any one of the first to seventh configurations, the cold plate may be configured such that the inlet is opposed to a central portion in the extending direction of the blade in the vertical direction (Z1-Z2) (eighth configuration).

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cold plate comprising:
a bottom wall that includes a lower surface to be in thermal contact with a heat generating component;
a top wall that covers an upper surface of the bottom wall;
a side wall that connects the bottom wall and the top wall, and defines a refrigerant flow path through which a refrigerant is capable of flowing;
an inlet through which the refrigerant is capable of flowing into the refrigerant flow path;
an outlet through which the refrigerant is capable of flowing out of the refrigerant flow path; and
a blade group that is in the refrigerant flow path and includes a plurality of blades extending linearly and arranged in a direction intersecting an extending direction of the plurality of blades; wherein
a plurality of the blade groups are arranged side by side with a gap in the extending direction of the plurality of blades; and
a plurality of the inlets are correspondingly positioned with respect to the plurality of blade groups.

2. The cold plate according to claim 1, wherein the outlet is located at an end of the refrigerant flow path in the extending direction of the plurality of blades.

3. The cold plate according to claim 1, further comprising:
a refrigerant supply path to supply the refrigerant to the refrigerant flow path; wherein
the refrigerant supply path is branched and connected to each of the plurality of inlets.

4. The cold plate according to claim 3, wherein
the refrigerant supply path is integral with the top wall; and
an end of the refrigerant supply path on an upstream side in a flowing direction of the refrigerant is opened to the side wall.

5. The cold plate according to claim 3, wherein the refrigerant supply path extends in a direction away from the outlet along the extending direction of the plurality of blades.

6. The cold plate according to claim 3, wherein the inlet extends in an arrangement direction of the plurality of blades, and is connected to the refrigerant supply path at one end in the arrangement direction of the plurality of blades.

7. The cold plate according to claim 1, further comprising:
a refrigerant discharge path through which the refrigerant is discharged from the refrigerant flow path; wherein
the refrigerant discharge path is connected to the outlet and extends in a direction away from the inlet along an extending direction of the plurality of blades.

8. The cold plate according to claim 3, further comprising:
a refrigerant discharge path through which the refrigerant is discharged from the refrigerant flow path; wherein
the refrigerant discharge path is connected to the outlet and extends in a direction away from the inlet along an extending direction of the plurality of blades.

9. The cold plate according to claim 1, wherein the inlet opposes, in a vertical direction, a central portion of the plurality of blades in the extending direction.
